(19) United States
(12) Patent Application Publication
(10) Pub. No.: US 2026/0123333 A1
(43) Pub. Date: Apr. 30, 2026

(54) BUFFER CHAMBER AND SUBSTRATE PROCESSING APPARATUS INCLUDING SAME

(71) Applicant: SEMES CO., LTD., Cheonan-si, (KR)

(72) Inventors: Jin Se PARK, Cheonan-si (KR); Yong Joon IM, Yongin-si (KR); Seung Hoon OH, Cheonan-si (KR)

(73) Assignee: SEMES CO., LTD., Cheonan-si (KR)

(21) Appl. No.: 19/004,671

(22) Filed: Dec. 30, 2024

(30) Foreign Application Priority Data
Dec. 29, 2023 (KR) 10-2023-0197503

(51) Int. Cl. H01L 21/67; H01L 21/687

(52) U.S. Cl. CPC H10P 72/0461; H10P 72/0402; H10P 72/0464; H10P 72/7602

(57) ABSTRACT

The present invention relates to a buffer chamber and a substrate processing apparatus including the buffer chamber. In more detail, the present invention relates to a buffer chamber that can maintain the atmosphere of a buffer unit at low humidity, and a substrate processing apparatus including the buffer chamber. According to an embodiment, the substrate processing apparatus includes: a processing module processing substrates; and an index module transferring substrates to the processing module from a container accommodating substrates, and putting substrates processed at the processing module into the container, wherein the processing module comprises: a transfer chamber having a transfer unit transferring substrates to the processing module; and a buffer chamber that is disposed between the index module and the transfer chamber and in which substrates are temporarily placed, the buffer chamber comprises: a housing providing a standby space; a door opening and closing the housing; a buffer unit in which substrates are placed in the standby space; a gas supply unit supplying gas to the standby space; and an exhaust unit exhausting the standby space, and pressures in the transfer chamber and the index module are different from each other.

### CROSS-REFERENCE TO RELATED APPLICATIONS

This application claims priority to and the benefit of Korean Patent Application No. 10-2023-0197503 filed in the Korean Intellectual Property Office on Dec. 29, 2023, the entire contents of which are incorporated herein by reference.

### TECHNICAL FIELD

The present invention relates to a buffer chamber and a substrate processing apparatus including the buffer chamber. In more detail, the present invention relates to a buffer chamber that can maintain the atmosphere of a buffer unit at low humidity, and a substrate processing apparatus including the buffer chamber.

### BACKGROUND ART

In general, various processes such as cleaning, deposition, photolithography, etching, and ion injection are performed to manufacture a semiconductor device. These processes are performed in a processing module and a substrate that has undergone each process and a substrate that waits for each process stand by for a predetermined time in a buffer unit. The atmosphere of the buffer unit needs to be controlled in order to prevent pattern collapse, substrate contamination, etc. while a substrate is on standby.

However, a buffer unit has an open structure, the front face thereof is connected with an index module, and the rear face thereof is connected with a processing module. Accordingly, when the pressure at the two sides are different, airflow flows to the buffer unit due to a pressure difference, so there is a problem that it is difficult to control the atmosphere of the buffer unit.

### SUMMARY OF THE INVENTION

An object of the present invention is to provide a buffer chamber that can stop airflow flowing to a buffer unit, and a substrate processing apparatus including the buffer chamber.

Further, an object of the present invention is to provide a buffer chamber that can control the atmosphere of a buffer unit, and a substrate processing apparatus including the buffer chamber.

Further, an object of the present invention is to provide a buffer chamber that can maintain the atmosphere of a buffer unit at low humidity, and a substrate processing apparatus including the buffer chamber.

The objects of the present invention are not limited thereto and other objectives not stated herein may be clearly understood by those skilled in the art from the following description.

The present invention provides a substrate processing apparatus. According to an embodiment, the substrate processing apparatus includes: a processing module processing substrates; and an index module transferring substrates to the processing module from a container accommodating substrates, and putting substrates processed at the processing module into the container, wherein the processing module comprises: a transfer chamber having a transfer unit transferring substrates to the processing module; and a buffer chamber that is disposed between the index module and the transfer chamber and in which substrates are temporarily placed, the buffer chamber comprises: a housing providing a standby space; a door opening and closing the housing; a buffer unit in which substrates are placed in the standby space; a gas supply unit supplying gas to the standby space; and an exhaust unit exhausting the standby space, and pressures in the transfer chamber and the index module are different from each other.

According to an embodiment, the supply unit may include a gas supply pipe connected with the housing, and the gas supply pipe may be connected to an upper portion of the housing.

According to an embodiment, the gas supply pipe may be provided in multiple instances and the gas supply pipes may be connected to an upper portion of the housing.

According to an embodiment, the exhaust unit may include an exhaust pipe connected to a lower portion of the housing and the exhaust pipe may be connected to the lower portion of the housing.

According to an embodiment, the exhaust pipe may be provided in multiple instances and the exhaust pipes may be connected to the lower portion of the housing.

According to an embodiment, the first opening has: an upper opening formed at a position corresponding to an area where the upper slots may be positioned; and a lower opening formed at a position corresponding to an area where the lower slots are positioned, and the first door comprises: a first upper door opening and closing the upper opening; and a first lower door actuated independently from the first upper door and opening and closing the lower opening.

According to an embodiment, the housing may include: a first door formed at a position corresponding to an area where the upper slots are positioned and opening and closing the housing; and a second door formed at a position corresponding to an area where the lower slots are positioned and opening and closing the housing.

According to an embodiment, the gas may not contain moisture.

The present invention provides a buffer chamber in which substrates are placed.

According to an embodiment, the buffer chamber includes: a housing providing a standby space; a door opening and closing the housing; a buffer unit in which substrates are placed in the standby space; a gas supply unit supplying gas to the standby space; and an exhaust unit exhausting the standby space, and wherein pressures at a first side of the buffer chamber and pressure at a second side facing the first side may be different from each other.

According to an embodiment, the gas supply unit may include a gas supply pipe connected the housing and the gas supply pipe may be connected to an upper portion of the housing.

According to an embodiment, the gas supply pipe may be provided in multiple instances and the gas supply pipes may be connected to an upper portion of the housing.

According to an embodiment, the exhaust unit includes an exhaust pipe connected to a lower portion of the housing and the exhaust pipe may be connected to the lower portion of the housing.

According to an embodiment, the exhaust pipe may be provided in multiple instances and the exhaust pipes may be connected to the lower portion of the housing.

According to an embodiment, the buffer unit may include a plurality of slots in which substrates are placed, the slots are provided such that the substrates may be horizontally stored therein, the slots may be stacked up and down, and the slots may include upper slots in which the substrates are stored after being processed, and lower slots in which the substrates are stored before being processed.

According to an embodiment, the housing may include: a first door formed at a position corresponding to an area where the upper slots are positioned and opening and closing the housing; and a second door formed at a position corresponding to an area where the lower slots are positioned and opening and closing the housing.

According to an embodiment, the gas may not contain moisture.

The present invention provides a substrate processing apparatus. According to an embodiment, the substrate processing apparatus includes: a processing module processing substrates; and an index module transferring substrates to the processing module from a container accommodating substrates, and putting substrates processed at the processing module into the container, wherein the processing module includes: a transfer chamber having a transfer unit transferring substrates to the processing module; and a buffer chamber that is disposed between the index module and the transfer chamber and in which substrates are temporarily placed, the buffer chamber includes: a housing providing a standby space; a door opening and closing the housing; a buffer unit in which substrates are placed in the standby space; a gas supply unit supplying gas to the standby space; and an exhaust unit exhausting the standby space, and the supply unit includes a gas supply pipe connected with the housing, the exhaust unit includes an exhaust pipe connected to a lower portion of the housing, and pressures in the transfer chamber and the index module are different from each other.

According to an embodiment, the buffer unit comprises a plurality of slots in which substrates are placed, the slots are provided such that the substrates are horizontally stored therein, the slots are stacked up and down, the slots comprise upper slots in which the substrates are stored after being processed, and lower slots in which the substrates are stored before being processed, and the housing comprises: a first door formed at a position corresponding to an area where the upper slots are positioned and opening and closing the housing; and a second door formed at a position corresponding to an area where the lower slots are positioned and opening and closing the housing.

According to an embodiment, the gas may be gas not containing moisture.

According to an embodiment of the present invention, the present invention can stop airflow flowing to the buffer unit.

Further, according to an embodiment of the present invention, the present invention can control the atmosphere of the buffer unit.

Further, according to an embodiment of the present invention, the present invention can maintain the atmosphere of the buffer unit at low humidity.

Effects of the present invention are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a plan view schematically showing a substrate processing apparatus according to an embodiment of the present invention.

FIG. 2 is a view schematically showing an embodiment of the liquid process chamber of FIG. 1.

FIG. 3 is a view schematically showing a buffer chamber according to an embodiment of the present invention.

FIG. 4 is a cross-sectional view showing a cross-section of the buffer chamber according to an embodiment of the present invention.

FIG. 5 is a view schematically showing a buffer unit according to an embodiment of the present invention.

FIG. 6 is a view showing a buffer chamber according to another embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

A wafer is exemplarily described as a target to be processed in this embodiment. However, the technical spirit of the present invention can be applied even to apparatuses that are used to process other kinds of substrates in addition to a wafer as a processing target.

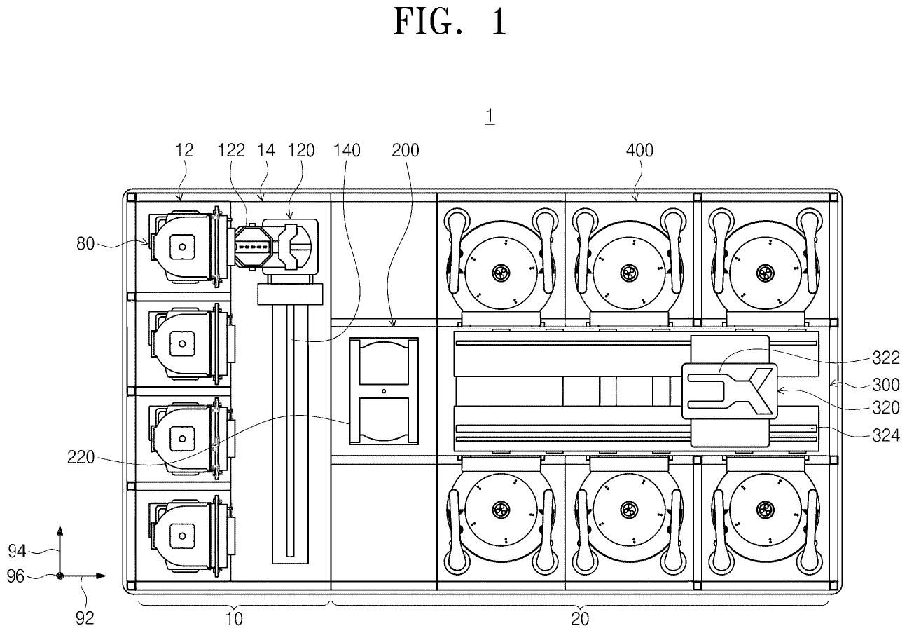

Embodiments of the present invention are described hereafter in detail with reference to the accompanying drawings. FIG. 1 is a plan view schematically showing a substrate processing apparatus according to an embodiment of the present invention.

Referring to FIG. 1, a substrate processing apparatus includes an index module 10, a processing module 20, and a control unit 30. According to an embodiment, the index module 10 and the processing module 20 are disposed in one direction. Hereafter, the direction in which the index module 10 and the processing module 20 are arranged is referred to as a first direction 92, a direction perpendicular to the first direction 92 when seen from above is referred to as a second direction 94, and a direction perpendicular to both of the first direction 92 and the second direction 94 is referred to as a third direction 96.

The index module 10 transfers substrates W to the processing module 20 from containers 80 accommodating the substrates W and puts the substrates W processed at the processing module 20 into the containers 80. The longitudinal direction of the index module 10 is provided in the second direction 94. The index module 10 has a loadport 12 and an index frame 14. The loadport 12 is positioned at the opposite side to the processing module 20 with the index frame 14 therebetween. The containers 80 accommodating substrates W are placed in the loadport 12. The load port 12 may be provided in multiple instances and the plurality of load ports 12 may be disposed in the second direction 94.

The container 80 may be a container for sealing such as a Front Open Unified Pod (FOUP). The container 80 may be placed in the loadport 12 by a worker or a conveying device (not shown) such as an overhead transfer, an overhead conveyor, or an automatic guided vehicle.

An index robot 120 is provided at the index frame 14. A guide rail 140 of which the longitudinal direction is provided in the second direction 94 is provided in the index frame 14 and the index robot 120 may be provided to be movable on the guide rail 140. The index robot 120 includes a hand 122 on which substrates W are placed and the hand 122 may be provided to be able to move forward and backward, rotate about the third direction 96, and move in the third direction 96. The hand 122 may be provided in multiple instances to be spaced apart from each other in the up-down direction and the hands 122 can move forward and backward independently from each other. A fan unit 16 may be provided over the index frame 14. The fan unit 16 supplies downward airflow inside the index frame 14. The inside of the index frame 14 can be maintained at a first pressure P1.

The processing module 20 includes a buffer chamber 200, a transfer chamber 300, and a process chamber 400. The buffer chamber 200 provides a space in which substrates W that are loaded into the processing module 20 and substrates W that are unloaded from the processing module 20 temporarily stay. The process chamber 400 performs a processing process of performing liquid processing on substrates W by supplying liquid onto the substrates W. The transfer chamber 300 transfers substrates W between the buffer chamber 200 and the liquid process chamber 400.

The longitudinal direction of the transfer chamber 300 may be provided in the first direction 92. The buffer chamber 200 may be disposed between the index module 10 and the transfer chamber 300. The liquid process chamber 400 is provided in multiple instances and may be disposed on a side of the transfer chamber 300. The liquid process chamber 400 and the transfer chamber 300 may be disposed in the second direction 94. The buffer chamber 200 may be positioned at an end of the transfer chamber 300.

According to an example, the liquid process chambers 400 may be disposed at both sides of the transfer chamber 300. The liquid process chambers 400 may be provided in an array of A×B (A and B are each a natural number of 1 or more) in the first direction 92 and the third direction 96, respectively, at each of both sides of the transfer chamber 300.

The transfer chamber 300 has a transfer robot 320. A guide rail 340 of which the longitudinal direction is provided in the first direction 92 is provided in the transfer chamber 300 and the transfer robot 320 may be provided to be movable on the guide rail 340. The transfer robot 320 includes a hand 322 on which substrates W are placed and the hand 322 may be provided to be able to move forward and backward, rotate about the third direction 96, and move in the third direction 96. The hand 322 may be provided in multiple instances to be spaced apart from each other in the up-down direction and the hands 322 can move forward and backward independently from each other. A fan unit 360 may be provided over the transfer chamber 300. The fan unit 360 supplies downward airflow inside the transfer chamber 300. The inside of the transfer chamber 300 can be maintained at a second pressure P2. The second pressure P may be different from the first pressure P1.

The buffer chamber 200 includes a buffer unit 230 in which substrates W are placed. The buffer units 230 may be disposed to be spaced apart from each other in the third direction 96. The buffer unit 200 is open on the front face and the rear face. The front face is a surface that faces the index module 10 and the rear face is a surface that faces the transfer chamber 300. The index robot 120 can approach the buffer chamber 200 through the front face and the transfer robot 320 can approach the buffer chamber 200 through the rear face. The detailed configuration, shape, etc. of the buffer chamber 200 are described below.

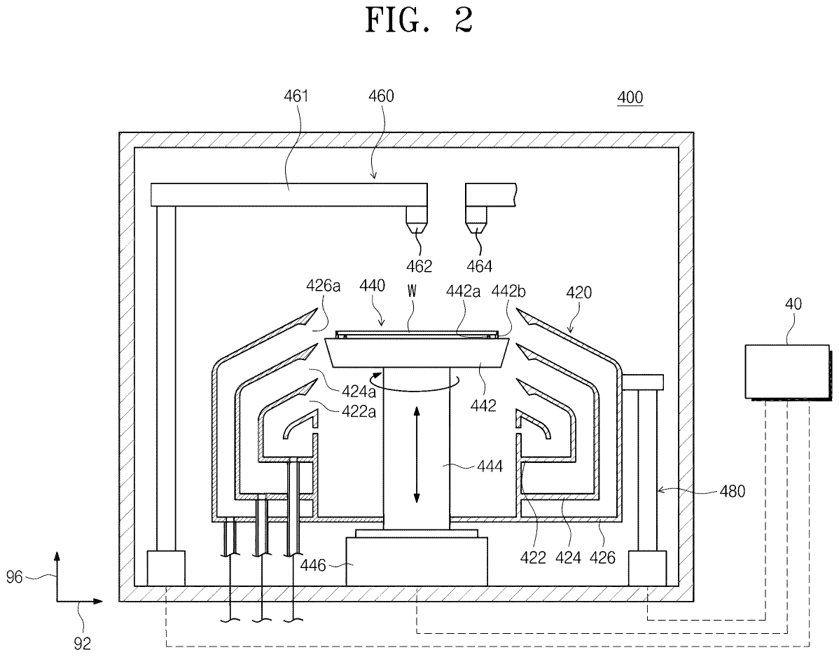

FIG. 2 is a view schematically showing an embodiment of the liquid process chamber 400 of FIG. 1. Referring to FIG. 2, the liquid process chamber 400 includes a housing 410, a cup 420, a supporting unit 440, a nozzle unit 460, an elevation unit 480, a supply unit, and a control unit.

The housing 410 is provided substantially in a rectangular prism shape. The cup 420, the supporting unit 440, and the liquid supply unit 460 are disposed in the housing 410.

The cup 420 has a processing space with an open top and substrates W are liquid-processed in the processing space. The supporting unit 440 supports substrates W in the processing space. The liquid supply unit 460 supplies liquid to a substrate W supported on the supporting unit 440. A plurality of kinds of processing liquids is provided and may be sequentially supplied to a substrate W. The elevation unit 480 adjusts the relative height between the cup 420 and the supporting unit 440.

According to an example, the cup 420 has a plurality of recovery baths 422, 424, and 426. The recovery baths 422, 424, and 426 each have a recovery space for recovering liquid used to treat a substrate. The recovery baths 422, 424, and 426 are each provided in a ring shape surrounding the supporting unit 440. The processing liquids splashed by rotation of a substrate W when the liquid processing process is performed flow into the recovery spaces through inlets 422a, 424a, and 426a of the recovery baths 422, 424, and 426, respectively. According to an example, the cup 420 has a first recovery bath 422, a second recovery bath 424, and a third recovery bath 426. The first recovery bath 422 is disposed to surround the supporting unit 440, the second recovery bath 424 is disposed to surround the first recovery bath 422, and the third recovery bath 426 is disposed to surround the second recovery bath 424. The second inlet 424a for supplying liquid into the second recovery bath 424 may be positioned higher than the first inlet 422a for supplying liquid into the first recovery bath 422, and the third inlet 426a for supplying liquid into the third recovery bath 426 may be positioned higher than the second inlet 424a.

The supporting unit 440 has a supporting plate 442 and an actuating shaft 444. The upper surface of the supporting plate 442 is provided substantially in a circular shape and may have a diameter larger than substrates W. Supporting pins 442a supporting the rear surface of a substrate W is provided at the center portion of the supporting plate 442 and are provided such that the upper ends thereof protrude from the supporting plate 442 to space a substrate W a predetermined distance from the supporting plate 442. Chuck pins 442b are provided on the edge portion of the supporting plate 442. The chuck pins 442b protrude upward from the supporting plate 442 and support the side of a substrate W to prevent the substrate W from separating from the supporting unit 440 when the substrate W is rotated. The actuating shaft 444 is driven by an actuator 446, is connected with the center of the underside of a substrate W, and rotates the supporting plate 442 about the center axis thereof.

The nozzle unit 460 has a first nozzle 462 and a second nozzle 464. The first nozzle 462 supplies a processing liquid to substrates W. The processing liquid may be a liquid at a higher temperature than the room temperature. According to an example, the processing liquid may be a phosphoric acid solution. The phosphoric acid solution may be a mixture of phosphoric acid and water. Selectively, the phosphoric acid solution may further contain other substances. For example, the other substance may be silicon. The second nozzle 464 supplies water onto substrates W. The water may be pure water or deionized water.

The first nozzle 462 and the second nozzle 463 are supported by different arms 461 and the arms 461 can be independently moved. Selectively, the first nozzle 461 and the second nozzle 462 may be mounted on the same arm and moved simultaneously.

Selectively, the liquid supply unit may further have one or a plurality of nozzles in addition to the first nozzle 462 and the second nozzle 464. The added nozzles can supply other kinds of processing liquids to substrates. For example, the other kinds of processing liquids may be an acid solution or a basic solution for removing contaminants from substrates. Further, the other kinds of processing liquids may be alcohol lower in surface tension than water. For example, the alcohol may be isopropyl alcohol.

The elevation unit 480 moves the cup 420 in the up-down direction. The relative height between the cup 420 and a substrate W is changed by up-down movement of the cup 420. Accordingly, the recovery baths 422, 424, and 426 that recover processing liquids are changed, depending on the kinds of treatment liquids that are supplied to substrates W, so it is possible to separately recover treatment liquids. Unlike the above description, the cup 420 may be fixed and the elevation unit 480 may move the supporting unit 440 in the up-down direction.

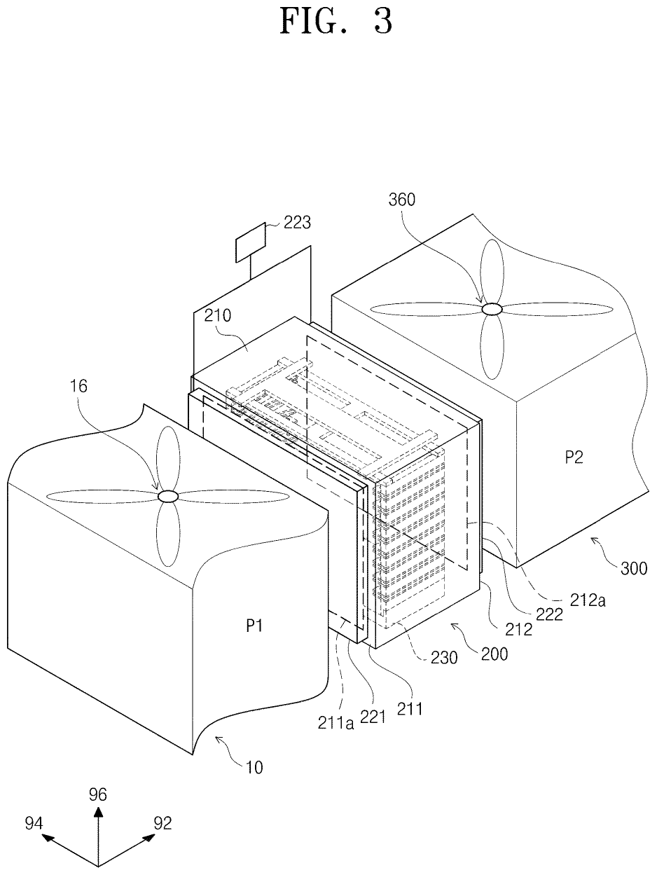

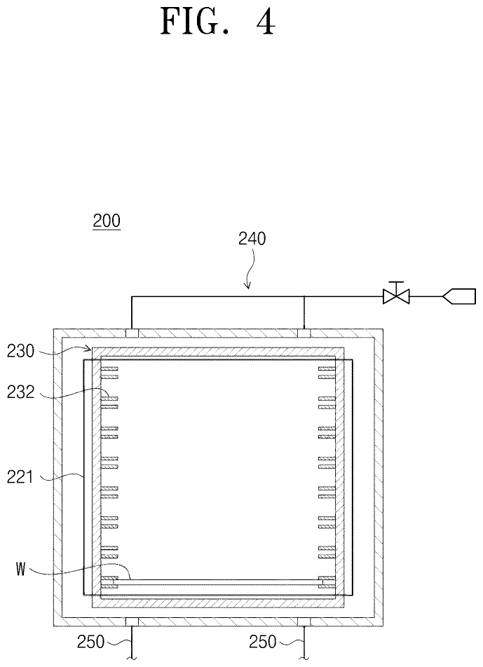

FIG. 3 is a view schematically showing a buffer chamber according to an embodiment of the present invention and FIG. 4 is a cross-sectional view showing a cross-section of the buffer chamber according to an embodiment of the present invention. Referring to FIG. 3 and FIG. 4, the buffer chamber 200 includes a housing 210, a door 220, a buffer unit 230, a gas supply unit 240, and an exhaust unit 250.

The housing 210 provides a standby space. The housing may be provided in a hexahedral shape. The housing 210 includes a first side 211 and a second side 212. The first side 211 may be a surface facing the index robot 120 of the index module 10. Alternatively, the first side 211 may be a surface facing the transfer robot 320 of the transfer chamber 300. Any one of the first side 211 and the second side 212 may be a surface facing the index robot 120 and the other one may be a surface facing the transfer robot 320. In the following description, it is assumed that the first side 211 is be a surface facing the index robot 120 and the second side 212 is a surface facing the transfer robot 320. The index robot 120 approaches the buffer unit 230 through the first side 211. A first opening 211a for loading and unloading substrates W is formed on the first side 211. A second opening 212a for loading and unloading substrates W is formed on the second side 212. The transfer robot 320 approaches the buffer unit 230 through the second side 212.

The door 220 includes a first door 221, a second door 222, and a door actuator 223. The first door 221 opens and closes the first opening 211a. The housing 210 is opened and closed by the first door 221. The second door 222 opens and closes the second opening 212a. The housing 210 is opened and closed by the second door 222. The first door 221 and the second door 222 may be formed in correspondence to the position where substrates W are placed in the buffer unit 230. The first door 221 and the second door 222 may be provided in multiple instances. Accordingly, door actuators for actuating the plurality of doors can be additionally provided.

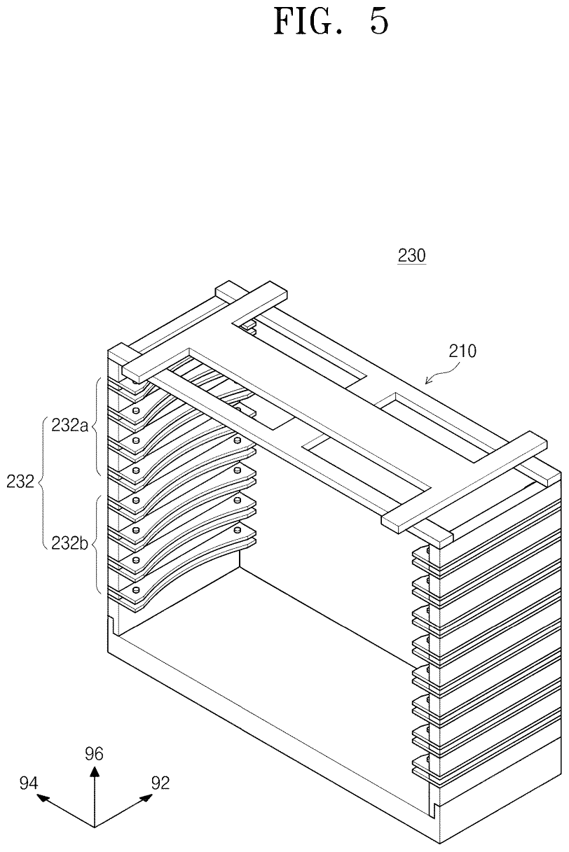

FIG. 5 is a view schematically showing a buffer unit according to an embodiment of the present invention. Referring to FIG. 5, the buffer unit 230 is disposed in the housing 210. The buffer unit 230 has a plurality of slots 232 in which substrates W are placed. The plurality of slots 232 may be provided such that substrates W are horizontally stored. The plurality of slots 232 may be provided to be stacked up and down. The buffer units 230 may be disposed to be spaced apart from each other in the third direction 96. According to an example, the slots 232 may be provided to support sides of substrates W. The slot 232 may be composed of upper slots 232a and lower slots 232b. The upper slots 232a may be locations where substrates W temporarily stand by after being processed in the process chamber 400. The lower slots 232b may be locations where substrates W stand by before being processed. According to an example, the upper slots 232a and the lower slots 232b each may be provided in four.

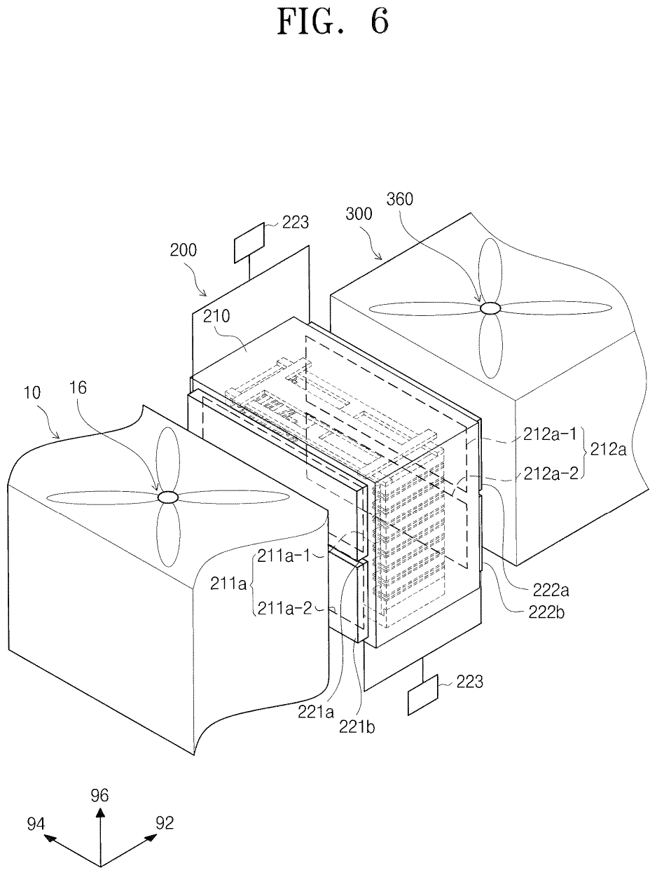

FIG. 6 is a view showing a buffer chamber according to another embodiment of the present invention. Referring to FIG. 6, a first wall 211 has a first upper opening 211a-1 and a first lower opening 211a-2. The first upper opening 211a-1 is formed at a position corresponding to the upper slots 232a. The first lower opening 211a-2 is formed at a position corresponding to the lower slots 232b. The first door 221 includes a first upper door 221a and a first lower door 221b. The first upper door 221a may be formed at a position corresponding to the first upper opening 211a-1. The first lower door 221b may be formed at a position corresponding to the first lower opening 211a-2. The first upper door 221a and the first lower door 221b can be independently actuated.

A second wall 212 has a second upper opening 212a-1 and a second lower opening 212a-2. The second upper opening 212a-1 is formed at a position corresponding to the upper slots 232a. The second lower opening 212a-2 is formed at a position corresponding to the lower slots 232b. The second door 221 includes a second upper door 222a and a second lower door 222b. The second upper door 222a may be formed at a position corresponding to the second upper opening 212a-1. The second lower door 221b may be formed at a position corresponding to the second lower opening 212a-2. The second upper door 222a and the second lower door 221b can be independently actuated.

The gas supply unit 240 supplies gas to the housing 210. The gas supply unit 240 may be formed on the upper wall 213 of the housing 210. The gas supply unit 240 includes a plurality of gas supply pipes 241. The gas may be low-humidity gas. The gas may be gas not containing moisture.

The exhaust unit 250 supplies gas to the housing 210. The exhaust unit 250 may be formed on the lower wall 214 of the housing 210. The exhaust unit 250 includes a plurality of exhaust pipes 251. Gas supplied from above is exhausted downward, so downward airflow is generated in the housing 210.

According to an embodiment of the present invention, the buffer chamber 200 is disposed between the index module 10 and the transfer chamber 300, and the buffer unit 230 is provided in the housing 210. Accordingly, even though the first pressure P1 and the second pressure P2 are different from each other, it is possible to stop the airflow that flows to the buffer unit 230.

Further, according to an embodiment of the present invention, the gas is gas not containing moisture, the gas supply unit 240 is provided over the housing 210, and the exhaust unit 250 is provided under the housing 210. Accordingly, low-humidity gas can generate downward airflow in the housing 210 and can maintain the inside of the housing 210 in a low-humidity atmosphere. Humidity may cause contamination of substrates W. By maintaining the atmosphere of the buffer chamber 200 in which substrates W stand by, contamination of substrates W can be prevented.

In the examples described above, the housing 210 is provided exemplarity as a hexahedron. However, the housing 210 is not limited thereto, and may be provided as a polyhedron, depending on the structure of the substrate processing apparatus.

The specification provides examples of the present invention. Further, the description provides an embodiment of the present invention and the present invention may be used in other various combination, changes, and environments. That is, the present invention may be changed or modified within the scope of the present invention described herein, a range equivalent to the description, and/or within the knowledge or technology in the related art. The embodiment shows an optimum state for achieving the spirit of the present invention and may be changed in various ways for the detailed application fields and use of the present invention. Therefore, the detailed description of the present invention is not intended to limit the present invention in the embodiment. Further, the claims should be construed as including other embodiments.

What is claimed is:

1. A substrate processing apparatus comprising:
a processing module processing substrates; and
an index module having an index robot transferring substrates to the processing module from a container accommodating substrates, and putting substrates processed at the processing module into the container,
wherein the processing module comprises:
a transfer chamber having a transfer robot transferring substrates to the processing module; and
a buffer chamber that is disposed between the index module and the transfer chamber and in which substrates are temporarily placed,
wherein the buffer chamber comprises:
a housing providing a standby space and having a first opening on a first side through which substrates are loaded inside;
a first door opening and closing the first opening; and
a buffer unit in which substrates are placed in the standby space.

2. The substrate processing apparatus of claim 1, comprising:
a gas supply unit supplying gas to the standby space; and
an exhaust unit exhausting the standby space.

3. The substrate processing apparatus of claim 2, wherein the index module further comprises:
an index frame equipped with the index robot; and
a first fan unit generating downstream airflow into the index frame,
the transfer chamber further comprises a second fan unit generating downstream airflow into a space to which the transfer robot is moved, and
a pressure of a space in which the index robot is provided and a space in which the transfer robot is provided are different.

4. The substrate processing apparatus of claim 2, wherein the gas supply unit comprises a gas supply pipe connected to an upper portion of the housing.

5. The substrate processing apparatus of claim 4, wherein the exhaust unit comprises an exhaust pipe connected to a lower portion of the housing.

6. The substrate processing apparatus of claim 1, wherein the buffer unit comprises a plurality of slots in which substrates are placed,
the slots are provided such that the substrates are horizontally stored therein,
the slots are stacked up and down, and
the slots comprise upper slots in which the substrates are stored after being processed, and lower slots in which the substrates are stored before being processed.

7. The substrate processing apparatus of claim 6, wherein the first opening has:
an upper opening formed at a position corresponding to an area where the upper slots are positioned; and
a lower opening formed at a position corresponding to an area where the lower slots are positioned, and
the first door comprises:
a first upper door opening and closing the upper opening; and
a first lower door actuated independently from the first upper door and opening and closing the lower opening.

8. The substrate processing apparatus of claim 2, wherein the first side is a surface facing the index robot.

9. The substrate processing apparatus of claim 2, wherein the first side is a surface facing the transfer robot.

10. The substrate processing apparatus of claim 1, wherein a second opening through which substrates are loaded inside is formed on a second side of the housing,
the buffer chamber further comprises a second door opening and closing the second opening, and
one of the first side and the second side is a surface facing the index robot and the other one is a surface facing the transfer robot.

11. The substrate processing apparatus of claim 2, wherein the gas is gas not containing moisture.

12. A buffer chamber in which substrates are placed, the buffer chamber comprising:
a housing providing a standby space and having a first opening on a first side through which substrates are loaded inside;
a first door opening and closing the first opening; and
a buffer unit in which substrates are placed in the standby space.

13. The buffer chamber of claim 12, comprising:
a gas supply unit supplying gas to the standby space; and
an exhaust unit exhausting the standby space,
wherein the gas supply unit comprises a gas supply pipe connected to an upper portion of the housing, and
the exhaust unit comprises an exhaust pipe connected to a lower portion of the housing.

14. The buffer chamber of claim 13, wherein the buffer unit comprises a plurality of slots in which substrates are placed,
the slots are provided such that the substrates are horizontally stored therein,
the slots are stacked up and down, and
the slots comprise upper slots in which the substrates are stored after being processed, and lower slots in which the substrates are stored before being processed.

15. The buffer chamber of claim 12, wherein the first opening has:
an upper opening formed at a position corresponding to an area where the upper slots are positioned; and
a lower opening formed at a position corresponding to an area where the lower slots are positioned, and
the first door comprises:
a first upper door opening and closing the upper opening; and
a first lower door actuated independently from the upper door and opening and closing the lower opening.

16. The buffer chamber of claim 12, wherein a second opening through which substrates are loaded inside is formed on a second side of the housing, and
the buffer chamber further comprises a second door opening and closing the second opening.

17. The buffer chamber of claim 13, wherein the gas is gas not containing moisture.

18. A substrate processing apparatus comprising:
a processing module processing substrates; and
an index module having an index robot transferring substrates to the processing module from a container accommodating substrates, and putting substrates processed at the processing module into the container,
wherein the processing module comprises:
a transfer chamber having a transfer robot transferring substrates to the processing module; and
a buffer chamber that is disposed between the index module and the transfer chamber and in which substrates are temporarily placed,
wherein the index module comprises:
an index frame equipped with the index robot; and
a first fan unit generating downstream airflow into the index frame,
wherein the transfer chamber further comprises a second fan unit generating downstream airflow into a space to which the transfer robot is moved,
a pressure of a space in which the index robot is provided and a space in which the transfer robot is provided are different,
the buffer chamber comprises:
a housing providing a standby space, having a first opening formed on a first side to load substrates inside, and having a second opening on a second side to load substrates inside;
a first door opening and closing the first opening;
a second door opening and closing the second opening;
a buffer unit in which substrates are placed in the standby space;
a gas supply unit supplying gas to the standby space; and
an exhaust unit exhausting the standby space.

19. The substrate processing apparatus of claim 18, wherein the buffer unit comprises a plurality of slots in which substrates are placed,
the slots are provided such that the substrates are horizontally stored therein,
the slots are stacked up and down,
the slots comprise upper slots in which the substrates are stored after being processed, and lower slots in which the substrates are stored before being processed, and
the housing comprises: a first door formed at a position corresponding to an area where the upper slots are positioned and opening and closing the housing; and a second door formed at a position corresponding to an area where the lower slots are positioned and opening and closing the housing.

20. The substrate processing apparatus of claim 19, wherein the gas is gas not containing moisture.
